(19) United States
(12) Patent Application Publication
(10) Pub. No.: US 2010/0045284 A1
(43) Pub. Date: Feb. 25, 2010

(54) CARBON NANOTUBE ACTUATOR

(75) Inventors: Yong Hyup Kim, Seoul (KR); Wal Jun Kim, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: SNU R&DB FOUNDATION, Seoul (KR)

(21) Appl. No.: 12/196,159

(22) Filed: Aug. 21, 2008

(51) Int. Cl. F03G 7/06; H02N 11/00; C23C 28/04; C25D 9/04; G01R 33/00

(52) U.S. Cl. 324/260; 310/300; 60/527; 205/159; 205/137; 324/207.11; 977/722; 977/847

(57) ABSTRACT

An actuator capable of flagellar motion is disclosed. The actuator comprises a carbon nanotube (CNT) rope and at least one metal/CNT composite part formed on the CNT rope.

### BACKGROUND

Among nanomaterials, carbon nanotubes (CNTs) are receiving increasing interest and study (e.g., in terms of research) in the field of materials science and technology. Carbon nanotubes possess outstanding mechanical, electrical and thermal properties. Carbon nanotubes have been used in various fields, such as, exhaust gas industry, semi-conducting devices, chemical sensors, or bulk additives of polymer composites. However, these applications have been done only on laboratory scale.

The conventional actuator using CNT technology has been developed by focusing on the outstanding electrochemical properties of the CNTs.

For example, there is an actuator in which the CNT is fabricated in the form of a sheet having a predetermined thickness and is attached on both sides of a polymer thin film sheet. The operation of the actuator uses the feature that, if electrical potential is applied to the CNT sheet in an electrolyte solution, a mechanical displacement is generated in one direction of the actuator due to an electrochemical reaction between the CNT sheet and ions in the electrolyte solution.

However, it is difficult to fabricate a uniform CNT sheet with conventional CNT technology. Moreover, the conventional actuator can only be operated in a specific electrolyte, thus restricting its operating environment. Furthermore, if the conventional actuator is used as the actuator of a micro robot, elements such as a power supply and a controller need to be installed in the robot body, thus resulting in not only a very complicated construction of the robot, but also a decrease in the robot's efficiency. Furthermore, the overall size of the actuator is large, and the driving force thereof is low.

### SUMMARY

In one embodiment an actuator comprises a carbon nanotube (CNT) rope and at least one metal/CNT composite part formed on the CNT rope.

The Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 is a diagram illustrating an actuator according to one embodiment.

FIG. 2 is a diagram illustrating an actuator according to another embodiment.

FIG. 3 is a diagram illustrating an actuator according to still another embodiment.

FIG. 4 is a diagram illustrating an expression calculating a deflection quantity according to the embodiment of FIG. 1.

FIG. 5 is a diagram illustrating an expression calculating a deflection quantity according to the embodiment of FIG. 2.

FIG. 6 is a diagram illustrating a method for manufacturing an actuator wherein a CNT rope is formed, in one embodiment.

FIG. 7 is a diagram illustrating a method for manufacturing an actuator wherein a metal/CNT composite part is formed, in one embodiment.

FIG. 8 shows a Scanning Electron Microscope (SEM) picture of an exterior of an actuator of the present disclosure.

FIG. 9 shows an SEM picture of across section of an actuator of the present disclosure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

As used herein, the term “rope” refers to a flexible member having an elongated shape, which corresponds to nothing but an expression having characteristics in the shape and the flexibility thereof. Therefore, limitations in accordance with other technical characteristics of a conventional “rope” should be excluded. One should keep in mind that any flexible member having an elongated shape can be interpreted as the “rope.”

An actuator capable of a flagellar motion is provided. In various embodiments, the actuator may comprise a simple structure, may be applied to various fields, may utilize characteristics of carbon nanotubes (CNTs), and may display flagellar characteristics as a result of for example, a force generated by a magnetic field.

In one embodiment an actuator comprises a CNT rope and at least one metal/CNT composite part formed on the CNT rope.

The at least one metal/CNT composite part may comprise a metal/CNT composite part, and the metal/CNT composite part may be formed on one end of the CNT rope in a longitudinal direction of the CNT rope.

The at least one metal/CNT composite part may comprise a plurality of metal/CNT composite parts, and the plurality of metal/CNT composite parts is positioned throughout the entire length of the CNT rope.

In another embodiment; an actuator may comprise a metal/CNT composite rope.

If a magnetic field surrounds the actuator in a state where one end of the actuator is fixed, a force is generated by the magnetic field. The force may be applied to at least one metal/CNT composite part, and thus the actuator displays a motion.

If the magnetic field surrounding the actuator is an alternating magnetic field, the actuator displays a flagellar motion.

In still another embodiment, a method for manufacturing an actuator comprises dipping a conductive metal tip into solution dissolved with metal ions and CNT, forming a CNT rope by raising the conductive metal tip from the solution, and forming a metal/CNT composite part on the CNT rope by applying an electric current between the conductive metal tip and the solution while raising the conductive metal tip from the solution.

Forming a metal/CNT composite part may be carried out at least one time after forming a CNT rope, so as to form the metal/CNT composite part on at least one portion of the CNT rope.

Forming a CNT rope and forming a metal/CNT composite part may be carried out a plurality of times in that order, so as to form a plurality of metal/CNT composite parts on the CNT rope. The metal/CNT composite parts are positioned throughout an entire length of the CNT rope.

In a further embodiment, a method for manufacturing an actuator comprises dipping a conductive metal tip into solution dissolved with metal ions and CNT, and forming a metal/CNT composite rope by applying an electric current between the conductive metal tip and the solution while raising the conductive metal tip from the solution.

The metal comprised in the metal/CNT composite may comprise a platable metal. The platable metal may be selected from a group consisting of Au, Ag, Ni, Co, Fe, Pt, Pd, Ni₄W, Cu₄W, WO₄ and TiO₂.

By way of example, the actuator can be used as an actuator for driving the micro robot. In this application, one end of the actuator may be fixed to a body of the micro robot.

A force may be generated by a magnetic field surrounding the micro robot placed in a fluid, and the force may be applied to the at least one metal/CNT composite part In response to the applied force, the actuator may display a motion.

If the force is generated by an alternating magnetic field surrounding the micro robot placed in a fluid, the actuator may display a flagellar motion so as to move the micro robot forwardly.

By way of another example, the actuator can be used as the magnetic sensor. In this application, one end of the actuator may be fixed to the body of the sensor.

A force may be generated by a magnetic field surrounding the magnetic sensor, and the force may be applied to at least one metal/CNT composite part. In response to the force, the actuator may display a motion. Thus, the magnetic sensor can sense the magnetic field.

If the deflection quantity of the actuator is measured, the strength of the magnetic field also can be calculated.

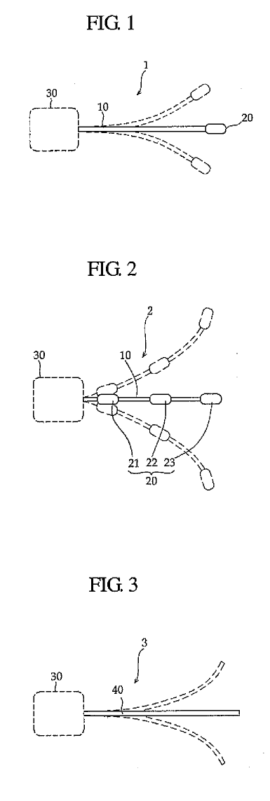

FIG. 1 is a diagram illustrating an actuator according to one embodiment FIG. 2 is a diagram illustrating an actuator according to another embodiment, and FIG. 3 is a diagram illustrating an actuator according to still another embodiment.

According to the embodiments shown in FIGS. 1 and 2, an actuator 1 and an actuator 2, respectively, comprises a CNT rope 10 and a metal/CNT composite part 20 formed on the CNT rope 10. Since CNT possesses superior mechanical characteristics, the mechanical characteristic required of the CNT rope 10 can be achieved even if the CNT rope 10 is formed slenderly, for example, in nanometer scale.

In particular, FIG. 1 illustrates the actuator 1 having the metal/CNT composite part 20 being formed on a portion of the CNT rope 10. As depicted in FIG. 1, the single metal/CNT composite part 20 is formed substantially on an end of the CNT rope 10 in a longitudinal direction of the CNT rope 10, but it is not necessary for the metal/CNT composite 20 to be formed substantially on the end of the CNT rope 10.

FIG. 2 illustrates the actuator 2 having a plurality of metal/CNT composite parts 20 being formed on the CNT rope 10. By way of example, three metal/CNT composite parts 20 are formed on the CNT rope 10, as denoted by reference numerals 21, 22, and 23, respectively, but the number of the metal/CNT composite parts 20 is not limited thereto. Further, the metal/CNT composite parts 20 can be positioned throughout the entire length of the CNT rope 10. In one embodiment the metal/CNT composite parts 20 may also be positioned so as to be evenly spaced apart from one another on the CNT rope 10.

FIG. 3 illustrates still another embodiment of an actuator 3 in which a rope is comprised of the metal/CNT composite material. That is, the actuator 3 includes a metal/CNT composite rope 40. One characteristic of CNT is that it is unstable (e.g., displays weak stability) in water. Since substantially the entire rope of the actuator 3 is composed of metal/CNT composite material, this results in the actuator 3 having increased stability (i.e., being more stable) in an aqueous environment.

The actuator of any of the embodiments described above may be operated in a similar manner. For example, a magnetic field can be generated around any one of the actuators 1, 2 or 3, where one end of each of the actuators 1, 2 or 3 is fixed. The magnetic field causes a magnetic force to be applied to the actuator 1, 2 or 3. The metal included in the metal/CNT composite part 20 (actuator 1 and actuator 2) or in the metal/CNT composite rope 40 (actuator 3) responds to the magnetic force so as to cause the CNT rope 10 (actuator 1 and actuator 2) or the metal/CNT composite rope 40 (actuator 3) to be deflected. Although a magnetic field is used to deflect the actuator in this example, any suitable force can be used to deflect the actuator.

In some embodiments, the magnetic field surrounding the actuator 1, 2 and 3 may be an alternating magnetic field. Thus, in response to the magnetic force generated by the alternating magnetic field, the CNT rope 10 of the actuator 1 and actuator 2, or the metal/CNT composite rope 40 of the actuator 3, displays a flagellar motion. The speed of the resulting flagellar motion of the actuator 1, 2 and 3 may be relatively fast, for example, at least dozens of movement times per second. This results in an increased efficiency of the actuator 1, 2 and 3.

As described above, the actuator 1 can comprise a single metal/CNT composite part 20 as shown in FIG. 1, which allows for ease of manufacturing. In the case of the actuator 2 where a plurality of the metal/CNT composite parts 20 is formed on the CNT rope 10, the deflection is relatively large, which results in the driving ability of the actuator 2 to be improved during flagellar motion.

The deflection quantity can be determined by using one of the beam deflection formulas below.

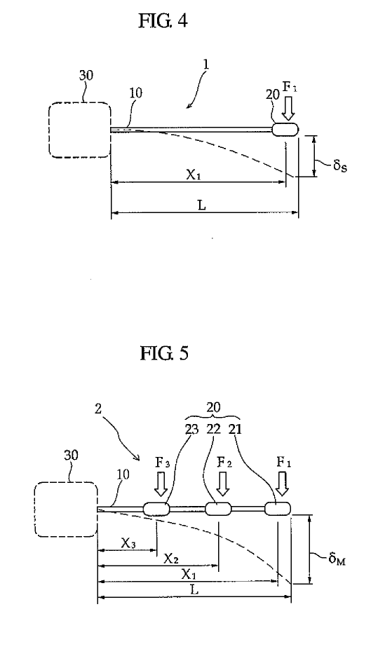

In the case of the actuator 1 having one metal/CNT composite part 20 positioned substantially at the end of the CNT rope 10 as shown in FIG. 4, the deflection quantity δₛ can be determined using the equation below:

$${δ}_{S} = \frac{{F}_{1} {x}_{1}^{2}}{6 EI} ( 3 L - {x}_{1} ) \qquad ( 1 )$$

wherein, x₁ denotes the distance between the fixed end of the actuator 1 and the metal/CNT composite part 20, L denotes the length of the actuator 1, F₁ denotes an external force which is applied to the metal/CNT composite part 20 to deflect the CNT rope 10 of the actuator 1, E denotes the modulus of elasticity of the actuator 1, and I denotes the area moment of inertia of the actuator 1.

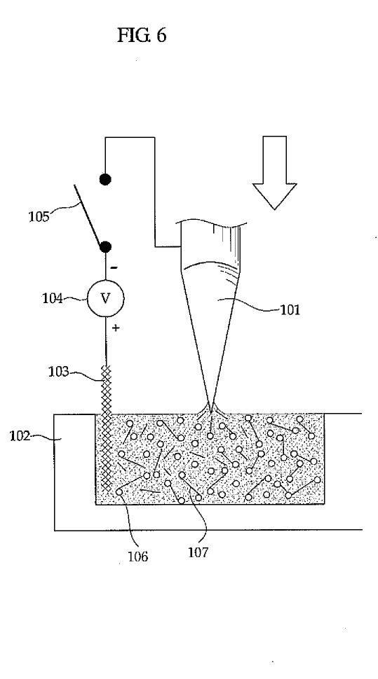

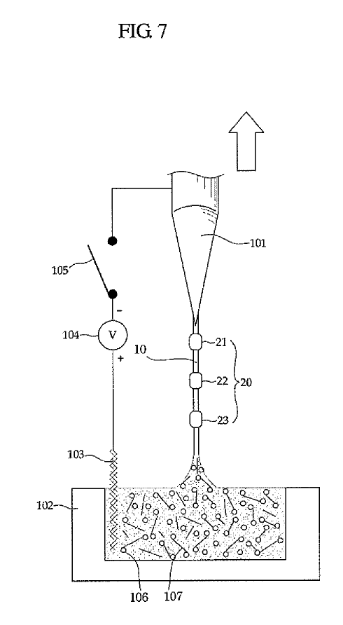

In the case of the actuator 2 having a plurality of metal/CNT composite parts 20 positioned substantially throughout the entire length of the CNT rope 10 as shown in FIG. 5, the deflection quantity δₘ can be determined using the equation below:

$${δ}_{M} = {\sum }_{1}^{n} \frac{{F}_{n} {x}_{n}^{2}}{6 EI} ( 3 L - {x}_{n} ) \qquad ( 2 )$$

wherein, xₙ denotes the distance between the fixed end of the actuator 2 and the nth metal/CNT composite part 20, L denotes the length of the actuator 2, Fₙ denotes an external force which is applied to the nth metal/CNT composite part 20 to deflect the CNT rope 10 of the actuator 2, E denotes the modulus of elasticity of the actuator 2, and I denotes the area moment of inertia of the actuator 2 (n is integer).

Through the above equations, the length of the CNT rope 10 or the size and location of the metal/CNT composite part 20 can be adjusted so as to design the actuator 1 or actuator 2 according to desired performance specifications. Further, when the actuator 1 or actuator 2 is adopted for a micro robot or magnetic sensor, the appropriate equation can be used to quantify the movement speed of the micro robot or to measure the quantity of the external force applied to the magnetic sensor.

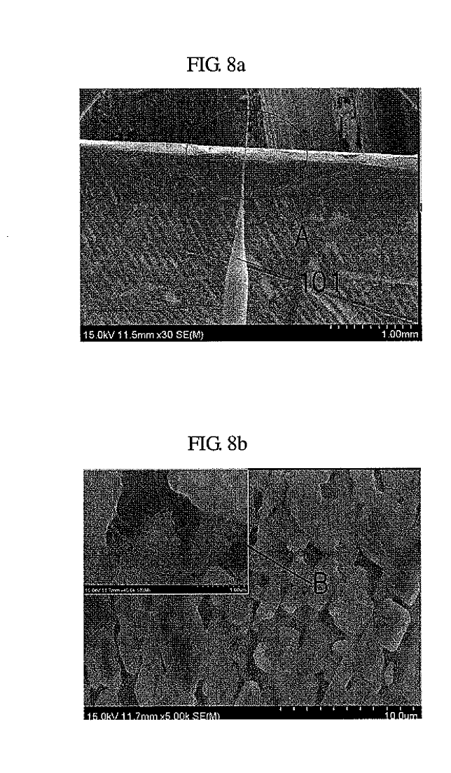

Hereinafter, a method for manufacturing an actuator will be described with reference to FIGS. 6 and 7.

As depicted in FIG. 6, a conductive metal tip 101 is first dipped in a solution contained in a bath 102. The solution is one in which metal ions 106 and CNT 107 are dissolved. The conductive metal tip 101 is then raised from the solution so as to form the CNT rope 10 (shown in FIG. 7).

Referring again to FIG. 6, a tungsten tip can be processed through etching or other similar processes to fabricate the conductive metal tip 101. Any metal can be used as the conductive metal tip 101 as long as the metal has a conductive property. Further, there is no restriction as to the shape of the conductive metal tip 101.

The bath 102 can be made of Teflon because Teflon does not react with the solution, but is not limited thereto. If the conductive metal tip 101 is immersed in the solution in the bath 102, a meniscus forms around the conductive metal tip 101 due to a capillary phenomenon. This causes the CNTs 107 to gather around the conductive metal tip 101. In this state, as depicted in FIG. 7, as the conductive metal tip 101 is gradually raised from the solution in the bath 102, the CNT rope 10 is formed. In FIG. 6, a downward arrow indicates the direction of dipping of the conductive metal tip 101 in the solution. In FIG. 7, an upward arrow indicates the direction of raising the conductive metal tip 101.

As depicted in FIGS. 6 and 7, an electrode 103, a power 104, and a switch 105, for example, can be used to apply an electric current between the conductive metal tip 101 and the solution. As described above, if the switch 105 is closed, the electric current is applied between the conductive metal tip 101 and the solution while the conductive metal tip 101 is being raised from the solution. Then, the metal ions in the solution are drawn toward the conductive metal tip 101 or the CNT rope 10 formed by the conductive metal tip 101, as depicted in FIG. 7. As a result, the metal/CNT composite part 20 is formed on the CNT rope 10.

Alternatively, if the switch 105 is open, the metal ions are not drawn toward the conductive metal tip 101 or the CNT rope 10. In this case, only the CNTs 107 gather around the conductive metal tip 101 or the CNT rope 10.

If the electric current is applied between the conductive metal tip 101 and the solution for a predetermined time period while raising the conductive metal tip 101 from the solution, the metal/CNT composite part 20 can be formed in a portion of the CNT rope 10.

Alternatively, the applying and non-applying the electric current between the conductive metal tip 101 and the solution may be repeated, while the conductive metal tip 101 is being raised from the solution. In this case, a plurality of metal/CNT composite parts 20 can be positioned substantially throughout the entire length of the CNT rope 10.

Alternatively, if the conductive metal tip 101 is dipped in the solution in which the metal ions and CNT are dissolved and the conductive metal tip 101 is raised from the solution while the electric current is applied between the conductive metal tip 101 and the solution, the metal/CNT composite rope 40 (shown in FIG. 3) can be formed.

A platable metal may be used for the metal comprised in the metal/CNT composite. The platable metal can be selected from a group consisting of Au, Ag, Ni, Co, Fe, Pt, Pd, Ni₄W, Cu₄W, WO₄ and TiO₂, but is not limited thereto.

The polarities of the conductive metal tip 101 and the electrode 103 may be determined according to (i.e., based on) the polarity of the metal ion dissolved in the solution. If the polarity of the metal ion in the solution is positive, for example, such as in the case of Au, Ag, Ni, Co, Fe, Pt, Pd, Ni₄W, Cu₄W and TiO₂, the polarity of the conductive metal tip 10 is negative and the polarity of the electrode 103 is positive. If the polarity of the metal ion in the solution is negative, for example, such as in the case of WO₄, the polarity of the conductive metal tip 10 is positive and the polarity of the electrode 103 is negative.

The actuator according to any of the embodiments described above (e.g., any of actuators 1, 2 and 3) can be used as an actuator for driving a micro robot. In this application, one end of the actuator is fixed to a body of the micro robot. In the case of the actuator 1, 2 and 3 of FIGS. 1 to 3, the body of the micro robot is denoted by the reference numeral 30. The magnetic field surrounding the micro robot generates a magnetic force, which in turn is applied to the metal/CNT composite part 20 of the actuator 1 or 2 or the metal/CNT composite rope 40 of the actuator 3. As a result, the CNT rope 10 shown in FIGS. 1 and 2 or the metal/CNT composite rope 40 shown in FIG. 3 is deflected. Alternatively, in response to an alternating magnetic field surrounding the micro robot, the CNT rope 10 or metal/CNT composite rope 40 displays a flagellar motion. Thus, the micro robot is able to move forwardly.

Accordingly, a micro robot having the actuator 1, 2 or 3, which displays a motion, for example, a flagellar motion, can be implemented without difficulty. For example, the micro robot placed in a fluid can move in response to a force applied to the actuator 1, 2, or 3. In particular, such a micro robot can be fabricated in a compact size and can have a simple structure, and is suitable for use in various fields. For example, the micro robot comprising the actuator according to any of the embodiments described above can be used in a living body.

Further, the actuator can be used as a magnetic sensor. In this application, one end of the actuator is fixed to the body 30 (shown in FIGS. 1 to 3) of the magnetic sensor. The magnetic field surrounding the magnetic sensor generates a magnetic force. In response to the magnetic force applied to the metal/CNT composite 20 of the actuator 1 or 2 or the metal/CNT composite rope 40 of the actuator 3, the CNT rope 10 or the metal/CNT composite rope 40 is deflected. Thus, the magnetic field can be sensed using the magnetic sensor to which the actuator is fixed. Further, if the deflection quantity of the actuator is measured as stated above, the strength of the magnetic field can be mathematically calculated.

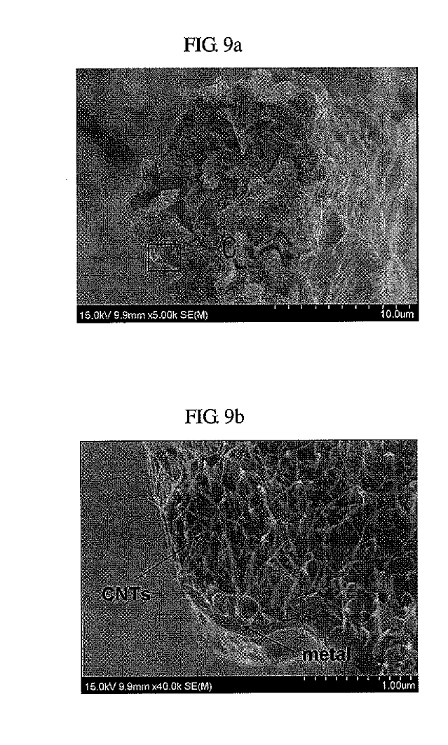

FIGS. 8 and 9 show a Scanning Electron Microscope (SEM) picture of an actuator manufactured using any one of the disclosed methods.

FIG. 8a shows an SEM picture of an exterior shape of the actuator, and FIG. 8b shows a magnified picture of the part “A” shown in FIG. 8a. In particular, the part “B” shown in FIG. 8b is the enlarged picture (40.0 k) of the exterior shape of the actuator.

FIG. 9a shows an SEM picture of a cut cross section of the metal/CNT composite part of the actuator, and FIG. 9b shows a magnified picture of the part “C” shown in FIG. 9a. FIG. 9b shows the entangled CNTs, represented by a white color, and the metal particles positioned between the CNTs.

As described above, the actuator according to the present disclosure has a simple structure and a relatively small number of elements (components). Further, the actuator can move in response to an externally generated force, for example, a magnetic force generated by a magnetic field surrounding the actuator. Thus, the actuator may not need a means for generating a power inside thereof. Moreover, the entire size of the actuator is decreed.

Further, the actuator according to the present disclosure can be applied or utilized in any environment as long as the actuator is placed within which a magnetic field is generated.

Still further, the actuator according to the present disclosure can be used in the micro robot or magnetic sensor placed in a fluid.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An actuator comprising:
a carbon nanotube (CNT) rope; and
at least one metal/CNT composite part formed on the CNT rope.

2. The actuator of claim 1, wherein the at least one metal/CNT composite part comprises a metal/CNT composite part.

3. The actuator of claim 2, wherein the metal/CNT composite part is formed on one end of the CNT rope in a longitudinal direction of the CNT rope.

4. The actuator of claim 1, wherein the at least one metal/CNT composite part comprises a plurality of metal/CNT composite parts.

5. The actuator of claim 4, wherein the plurality of metal/CNT composite parts are positioned throughout an entire length of the CNT rope.

6. The actuator of claim 1, wherein the metal/CNT composite comprises a platable metal.

7. The actuator of claim 6, wherein the platable metal is selected from the group consisting of Au, Ag, Ni, Co, Fe, Pt, Pd, Ni₄W, Cu₄W, WO₄ and TiO₂.

8. The actuator of claim 1, wherein the CNT rope is deflected in response to a force applied to the at least one metal/CNT composite part.

9. The actuator of claim 8, wherein the force is generated by a magnetic field surrounding the actuator.

10. An actuator comprising a metal/CNT composite rope.

11. The actuator of claim 10, wherein the metal/CNT composite rope comprises a platable metal.

12. The actuator of claim 11, wherein the platable metal is selected from the group consisting of Au, Ag, Ni, Co, Fe, Pt, Pd, N₄W, Cu₄W, WO₄ and TiO₂.

13. The actuator of claim 10, wherein the metal/CNT composite rope is deflected in response to a force applied to the metal/CNT composite rope.

14. The actuator of claim 13, wherein the force is generated by a magnetic field surrounding the actuator.

15. A method for manufacturing an actuator, comprising:
dipping a conductive metal tip into solution dissolved with metal ions and CNT;
forming a CNT rope by raising the conductive metal tip from the solution; and
forming a metal/CNT composite part on the CNT rope by applying an electric current between the conductive metal tip and the solution while raising the conductive metal tip from the solution.

16. The method of claim 15, wherein forming a metal/CNT composite part is carried out at least one time after forming a CNT rope, so as to form the metal/CNT composite part on at least one portion of the CNT rope.

17. The method of claim 15, wherein forming a CNT rope and forming a metal/CNT composite part are carried out a plurality of times in that order, so as to form a plurality of the metal/CNT composite parts positioned throughout an entire length of the CNT rope.

18. The method of claim 15, wherein the metal/CNT composite comprises a platable metal.

19. The method of claim 18, wherein the platable metal is selected from the group consisting of Au, Ag, Ni, Co, Fe, Pt, Pd, N₄W, Cu₄W, WO₄ and TiO₂.

20. A method for manufacturing an actuator, comprising:
dipping a conductive metal tip into solution dissolved with metal ions and CNT; and
forming a metal/CNT composite rope by applying an electric current between the conductive metal tip and the solution while raising the conductive metal tip from the solution.

21. The method of claim 20, wherein the metal/CNT composite comprises a platable metal.

22. The method of claim 21, wherein the platable metal is selected from the group consisting of Au, Ag, Ni, Co, Fe, Pt Pd, N₄W, Cu₄W, WO₄ and TiO₂.

23. A method for driving an actuator, the actuator comprising at least one metal/CNT composite part, one end of the actuator being fixed, comprising:
generating a magnetic field surrounding the actuator,
wherein the magnetic field generates a force, further wherein the force is applied to the metal/CNT composite part causing the actuator to display a motion.

24. The method of claim 23, wherein the magnetic field surrounding the actuator is an alternating magnetic field, and thus the actuator displays a flagellar motion.

25. The method of claim 23, wherein the actuator further comprises a CNT rope on which the at least one metal/CNT composite part is formed, further wherein the CNT rope is deflected in response to the force applied to the metal/CNT composite part.

26. The method of claim 23, wherein the at least one metal/CNT composite part comprises a metal/CNT composite rope, further wherein the metal/CNT composite rope is deflected in response to the force applied to the metal/CNT composite rope.

27. A micro robot comprising:
a body; and
an actuator comprising at least one metal/CNT composite part one end of the actuator being fixed to the body.

28. The micro robot of claim 27, wherein the actuator displays a motion in response to an applied force.

29. The micro robot of claim 28, wherein the force is generated by an alternating magnetic field surrounding the micro robot placed in a fluid, and thus the actuator displays a flagellar motion.

30. The micro robot of claim 27, wherein the actuator further comprises a CNT rope on which the at least one metal/CNT composite part is formed, further wherein the CNT rope is deflected in response to the force applied to the metal/CNT composite part.

31. The micro robot of claim 27, wherein the at least one metal/CNT composite part comprises a metal/CNT composite rope, further wherein the metal/CNT composite rope is deflected in response to the force applied to the metal/CNT composite rope.

32. A magnetic sensor comprising:
a body; and
an actuator comprising at least one metal/CNT composite part, one end of the actuator being fixed to the body.

33. The magnetic sensor of claim 32, wherein the actuator displays a motion in response to an applied force.

34. The magnetic sensor of claim 33, wherein the force is generated by a magnetic field surrounding the magnetic sensor.

35. The magnetic sensor of claim 34, wherein the magnetic sensor senses the strength of the magnetic field by measuring the deflection quantity of the actuator.

36. The magnetic sensor of claim 32, wherein the actuator further comprises a CNT rope on which the at least one metal/CNT composite part is formed.

37. The magnetic sensor of claim 32, wherein the at least one metal/CNT composite part comprises a metal/CNT composite rope.
